(19) United States
(12) Patent Application Publication
(10) Pub. No.: US 2026/0096098 A1
(43) Pub. Date: Apr. 2, 2026

(54) MANAGING ISOLATING STRUCTURES IN SEMICONDUCTOR DEVICES

(71) Applicant: Yangtze Memory Technologies Co., Ltd., Wuhan (CN)

(72) Inventors: Chao YAN, Wuhan (CN); Zhangyi LI, Wuhan (CN); Simin LIU, Wuhan (CN); Sizhe LI, Wuhan (CN); Jianlan WEI, Wuhan (CN); Zongliang HUO, Wuhan (CN)

(21) Appl. No.: 18/932,233

(22) Filed: Oct. 30, 2024

(30) Foreign Application Priority Data
Sep. 30, 2024 (CN) 202411392350.7

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

The present disclosure relates to methods, devices, and systems for managing isolating structures in semiconductor devices. An example semiconductor device includes a first stack of conductive layers and isolating layers extending along a first direction and alternating with each other along a second direction perpendicular to the first direction. The semiconductor device further includes a gate line slit structure extending through the first stack along the second direction, and a first isolating structure including a first portion in the first stack and a second portion in the gate line slit structure. The first portion of the first isolating structure is in contact with an isolating layer of the first stack. A size of the first portion of the first isolating structure is greater than a size of the isolating layer along the second direction.

### CROSS-REFERENCE TO RELATED APPLICATIONS

This application claims priority to Chinese Patent Application No. 202411392350.7, filed on Sep. 30, 2024, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing isolating structures in semiconductor devices.

One aspect of the present disclosure features a semiconductor device. The semiconductor device includes a first stack of conductive layers and isolating layers extending along a first direction and alternating with each other along a second direction perpendicular to the first direction. The semiconductor device further includes a gate line slit structure extending through the first stack along the second direction, and a first isolating structure including a first portion in the first stack and a second portion in the gate line slit structure. The first portion of the first isolating structure is in contact with an isolating layer of the first stack. A size of the first portion of the first isolating structure is greater than a size of the isolating layer along the second direction.

In some implementations, the semiconductor device further includes more than one first isolating structure distanced from each other and arranged along the first direction.

In some implementations, the size of the first portion is greater than a size of the second portion along the second direction.

In some implementations, the first portion of the first isolating structure is between two conductive layers of the first stack along the second direction.

In some implementations, the first isolating structure includes a dielectric material or a semiconductor material.

In some implementations, the semiconductor device further includes a second stack of conductive layers and isolating layers extending along the first direction and alternating with each other along the second direction. The second stack is adjacent to the first stack along the second direction. The semiconductor device includes a second isolating structure between the first stack and the second stack along the second direction.

In some implementations, a portion of the gate line slit structure penetrates through the second portion of the first isolating structure. The portion of the gate line slit structure includes a plurality of cylinders that are arranged along the first direction.

In some implementations, the portion of the gate line slit structure further includes a structure having a surface that includes a series of curves.

In some implementations, the semiconductor device further includes channel structures extending through the first stack along the second direction. A size of the gate line slit structure is greater than a size of a channel structure along a third direction perpendicular to the first direction and the second direction.

In some implementations, a size of a cylinder of the plurality of cylinders is greater than the size of the channel structure along the third direction.

In some implementations, a surface of the gate line slit structure includes a series of curves.

Another aspect of the present disclosure features a semiconductor device. The semiconductor device includes a first stack of conductive layers and isolating layers extending along a first direction and alternating with each other along a second direction perpendicular to the first direction, a gate line slit structure extending through the first stack along the second direction, and one or more first isolating structures each including a first portion in the first stack and a second portion in the gate line slit structure. The one or more first isolating structures are distanced from each other and arranged along the first direction. A size of a first isolating structure of the one or more first isolating structures is greater than a size of the gate line slit structure along a third direction perpendicular to the first direction and the second direction.

In some implementations, the semiconductor device includes an array region and a connection region adjacent to the array region along the first direction. The first stack is in the array region and a part of the connection region. A first portion of the one or more first isolating structures are in the array region, and a second portion of the one or more first isolating structures are in the part of the connection region.

In some implementations, a size of the first portion of the first isolating structure is greater than a size of the second portion of the first isolating structure along the second direction.

In some implementations, the semiconductor device further includes a second stack of conductive layers and isolating layers extending along the first direction and alternating with each other along the second direction. The second stack is adjacent to the first stack along the second direction. The semiconductor device includes one or more second isolating structures between the first stack and the second stack along the second direction. The one or more second isolating structures are arranged along the first direction.

In some implementations, the semiconductor device further includes channel structures extending through the first stack along the second direction. A size of the gate line slit structure is greater than a size of a channel structure along a third direction perpendicular to the first direction and the second direction.

In some implementations, a surface of the gate line slit structure includes a series of curves.

Another aspect of the present disclosure features a method of forming a semiconductor device. The method includes forming a stack of conductive layers and isolating layers extending along a first direction and alternating with each other along a second direction perpendicular to the first direction, forming a gate line slit structure extending through the stack along the second direction, and forming one or more isolating structures each including a first portion in the stack and a second portion in the gate line slit structure. The one or more isolating structures are distanced from each other and arranged along the first direction. A size of a first isolating structure of the one or more isolating structures is greater than a size of the gate line slit structure along a third direction perpendicular to the first direction and the second direction.

In some implementations, the method further includes forming a first stack of sacrificial layers and isolating layers alternating with each other along the second direction, etching the first stack to form one or more trenches that are distanced from each other and arranged along the first direction, filling the one or more trenches with a dielectric material to form the one or more isolating structures, forming, on the first stack, a second stack of sacrificial layers and isolating layers alternating with each other along the second direction, forming gate line holes extending through the second stack of sacrificial layers and isolating layers, the one or more isolating structures, and the first stack of sacrificial layer and isolating layers, where the gate line holes are arranged along the first direction, and forming a gate line space by expanding the gate line holes. The gate line holes in the first stack and the second stack are connected with each other along the first direction to form the gate line space. At least a portion of the gate line holes in the one or more isolating structures are separate from each other.

In some implementations, forming the stack of conductive layers and isolating layers includes replacing the sacrificial layers of the first stack and the second stack with conductive layers. Forming the gate line slit structure includes filling the gate line space with a semiconductor material.

The details of one or more implementations of the subject matter of this present disclosure are set forth in the accompanying drawings and the description below. Other features, aspects, and advantages of the subject, matter will become apparent from the description, the drawings, and the claims.

### BRIEF DESCRIPTION OF DRAWINGS

FIGS. 1A-1C illustrate an example semiconductor device.

FIGS. 2A-2D illustrate an example semiconductor structure at a stage during a fabrication process to manufacture the example semiconductor device of FIGS. 1A-1C.

FIG. 3A illustrates an example isolating structure.

FIG. 3B illustrates another example isolating structure.

FIGS. 4A-4F illustrate an example process of manufacturing a semiconductor device.

FIG. 5 illustrates another example semiconductor device.

FIG. 6 illustrates a flow chart of an example process of manufacturing a semiconductor device.

FIG. 7 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for memory devices with a higher density, a memory device (e.g., a 3D NAND flash memory) can include a stack having a large number of layers along a vertical direction. As the number of layers in the stack increases, the stack is more susceptible to collapsing. For example, during fabrication processes of the memory device, the stack may collapse towards a gate line space that extends vertically through the stack. The gate line space can be used for forming a gate line slit structure that divides the stack into memory blocks.

The present disclosure provides techniques to help avoid a stack of a memory device from collapsing. A memory device can include a stack of conductive layers and isolating layers that extend in a horizontal direction and alternate with each other along a vertical direction, and a gate line slit structure that extends vertically through the stack. The memory device can have an array region and a connection region adjacent to the array region along the horizontal direction. A memory cell array can be formed in the array region, and contact structures can be formed in the connection region to connect the memory cell array to control circuits. The gate line slit structure can extend along the horizontal direction through the array region and the connection region. In some implementations, the memory device can include isolating structures that are distanced from one another and arranged along the horizontal direction. Each isolating structure has a first portion in the stack (e.g., between two conductive layers of the stack), and a second portion in the gate line slit structure. The isolating structures can serve as bridging structures to offer mechanical support to the stack, so that the stack is less likely to collapse towards the gate line space during the fabrication process.

Techniques of the present disclosure can provide one or more of the following technical advantages and/or benefits. For example, by having isolating structures to offer mechanical support, the stack is more stable and less susceptible to collapsing. For another example, compared to techniques to stabilize the stack by changing the shape of the gate line slit structure, the techniques of the present disclosure do not require extra space on the memory die, which is more cost efficient. Further, the isolating structures are only arranged in selected areas of the connection region and the array region. Areas of the connection region where contact structures are formed do not include the isolating structure. Therefore, the process of forming the contact structures in the connection region can remain the same as if no isolating structures are provided. In comparison, if a layer that covers the entire connection region is used as a bridging structure to stabilize the stack, different or extra steps may be needed to form the contact structures in the connection region. In some implementations, different or more technical advantages may be achieved.

The described techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), universal flash storage (UFS), or solid-state drives (SSDs), embedded systems, among others.

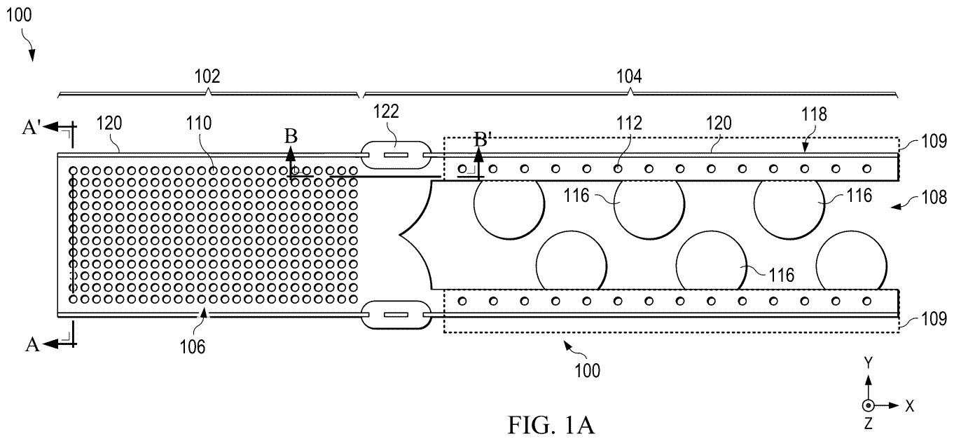

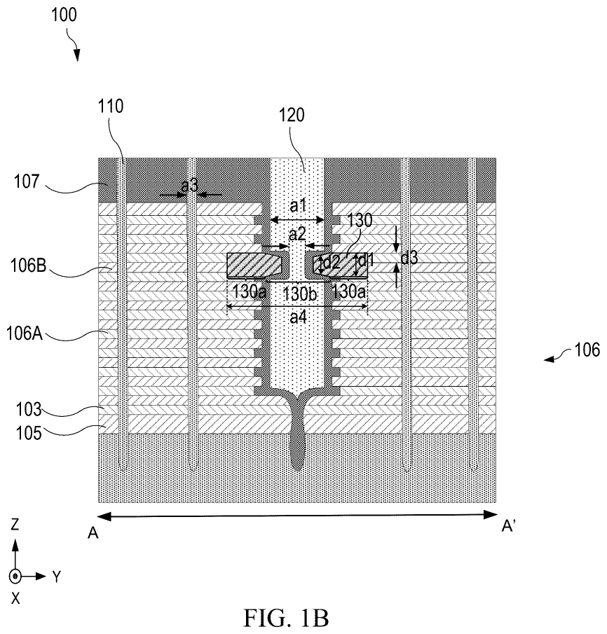

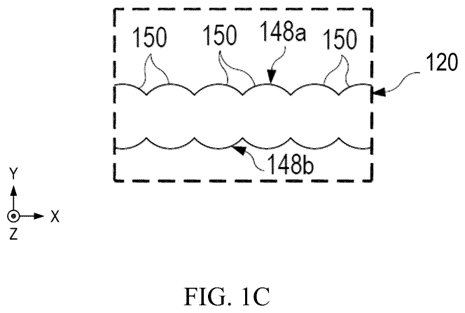

It is noted that X, Y, and Z axes (also referred to as X, Y, and Z directions) are included in FIGS. 1A-3B to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a top view of an example semiconductor device 100. In some implementations, the semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1A, the semiconductor device 100 includes an array region 102 and a connection region 104 adjacent to the array region 102 along a first horizontal direction (e.g., the X direction). It is understood that the example in FIG. 1A is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along the X direction. In some other instances, the semiconductor device 100 can have two array regions 102 and a connection region 104 between the two array regions 102 along the X direction.

The semiconductor device 100 includes a stack 106 of alternating conductive layers and isolating layers (e.g., conductive layers 106A and isolating layers 106B as shown in FIG. 1B). In some implementations, a part of the stack 106 can be in the array region 102, and another part of the stack 106 can be in a tunnel region 109 of the connection region 104. The semiconductor device 100 further includes a stack 108 of alternating dielectric layers and isolating layers. In some implementations, the stack 108 can be in the connection region 104. The stack 106 is connected to the stack 108.

The semiconductor device 100 can include an array of channel structures 110 extending through the stack 106 in the array region 102. Each channel structure 110 can be used to form a string of memory cells coupled in serial along a vertical direction (e.g., Z direction) perpendicular to the first horizontal direction. In some implementations, the semiconductor device 100 can include dummy channel structures 112 (also referred to as dummy memory strings) for process variation control during fabrication and/or for additional mechanical support. The dummy channel structures 112 can extend through the stack 106 in the tunnel region 109. In some implementations, the dummy channel structures 112 can be in one or more dummy regions or peripheral regions (not shown in FIG. 1A).

The semiconductor device 100 can include contact structures 116 in the connection region 104. A contact structure 116 can be configured to connect a corresponding one of the conductive layers of the stack 106 to a control circuit.

The semiconductor device 100 can include one or more gate line slit structures 120. Each gate line slit structure 120 can extend along the X direction. The gate line slit structure 120 can extend into both the array region 102 and the connection region 104. Regions around the gate line slit structures 120 in the connection region 104 can be used as the tunnel region 109. In some implementations, the gate line slit structure 120 can divide an array region 102 into multiple memory blocks. For example, a memory block (as shown in FIG. 1A) can be arranged between two memory blocks (not shown in FIG. 1A) along a second horizontal direction (e.g., the Y direction) in the array region 102, where the gate line slit structures 120 are boundaries that separate adjacent memory blocks. In some implementations, the gate line slit structure 120 can function as a common source contact for the channel structures 110 in the array region 102.

As shown in FIG. 1A, each gate line slit structure 120 can include multiple segments separated and spaced by separating structures 122. In some implementations, a separating structure 122 can separate a first portion of a gate line slit structure 120 that is in the array region 102 from a second portion of the gate line slit structure 120 that is in the connection region 104, so that different etching processes can be implemented for different portions of the gate line slit structure 120. For example, a first etching process can be implemented to etch away sacrificial layers (e.g., sacrificial layers 106D of FIG. 1B) in the array region 102 through the first portion of the gate line slit structure 120. A second etching process can be implemented to etch away sacrificial layers in the tunnel region 109 through the second portion of the gate line slit structure 120. Conductive layers (e.g., conductive layers 106A of FIG. 1B) can be formed in replace of the sacrificial layers in the array region 102 and in the tunnel region 109. In some implementations, the semiconductor device 100 can include one or more separating structures 122. The separating structures can eliminate or reduce stress built in the gate line slit structure 120 during the fabrication process, for example, preventing the gate line slit structure 120 from bending or cracking.

In some implementations (not shown in FIG. 1A), the gate line slit structure 120 can further include one or more segments extending along the second horizontal direction. In some implementations, the gate line slit structure 120 can include multiple segments that are connected with other and intersecting with each other (e.g., forming the gate line slit structure 120 into an H shape or a T shape). In some implementations, the segments of each gate line slit structure 120 can have similar or a same width (e.g., measured along the Y direction). In some other implementations, the segments of each gate line slit structure 120 can have different widths (e.g., measured along the Y direction). In some implementations, along the Y direction, a width of the segment of the gate line slit structure 120 in the connection region 104 is larger than a width of the segment of the gate line slit structure 120 in the array region 102. For example, the width of the segment in the connection region 104 can be approximately 1.5 to 2 times that of the segment in the array region 102.

FIG. 1B illustrates a cross-sectional view of the semiconductor device 100 along cut line AA′ of FIG. 1A. The semiconductor device 100 includes a substrate 101, a surface layer 107 made of a dielectric material (e.g., silicon oxide), and the stack 106 of alternating conductive layers 106A and isolating layers 106B. Each conductive layer 106A and each isolating layer 106B extend along the X direction. The conductive layers 106A and the isolating layers 106B alternate with each other along the Z direction. In some implementations, the semiconductor device 100 can also include an oxide layer 105 and a semiconductor layer 103 (e.g., made of polysilicon, amorphous silicon, etc.) between the substrate 101 and the stack 106. The semiconductor device can include a plurality of channel structures 110 extending along the Z direction through the stack 106. Each channel structure 110 can include, from the outer edge to the center of the channel structure 110, an isolating layer (e.g., a silicon oxide layer), a dielectric layer (e.g., a silicon nitride layer), an isolating layer (e.g., a silicon oxide layer), and a channel layer (e.g., a polysilicon layer). The plurality of channel structure 110 can be arranged along the X direction and/or the Y direction.

The semiconductor device 100 includes one or more gate line slit structures 120 that extend along the Z direction through the stack 106. The gate line slit structures 120 can include one of a semiconductor material (e.g., polysilicon), a high-K dielectric material (e.g., hafnium oxide, zirconium oxide, aluminum oxide, tantalum oxide, lanthanum oxide, or any combination thereof), a dielectric material (e.g., silicon oxide) or a sacrificial material (e.g., carbon). The gate line slit structure 120 can divide the stack 106 in the array region 102 into multiple memory blocks. For example, as shown in FIG. 1B, the gate line slit structure 120 is the boundary between a first memory block 132a and a second memory block 132b.

FIG. 1C illustrates an enlarged view of the gate line slit structure 120 of FIGS. 1A-1B. As shown in FIG. 1C, the gate line slit structure 120 can have at least two non-flat surfaces 148a and 148b opposite to each other (e.g., along the Y direction). Each of the two surfaces 148a and 148b includes a series of curves connected together. For example, the surface 148a includes curves 150 connected with one another along the X direction. In other words, the surfaces 148a and 148b are wave-like or caterpillar-like. In some implementations, a cross section of the gate line slit structure 120 has a shape of partial circles arranged in a line and connected together. The cross section of the gate line slit structure 120 is in the X-Y plane (e.g., perpendicular to the vertical direction).

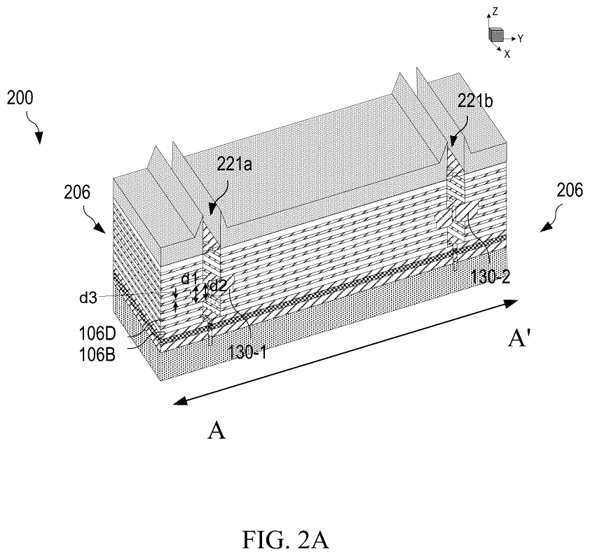

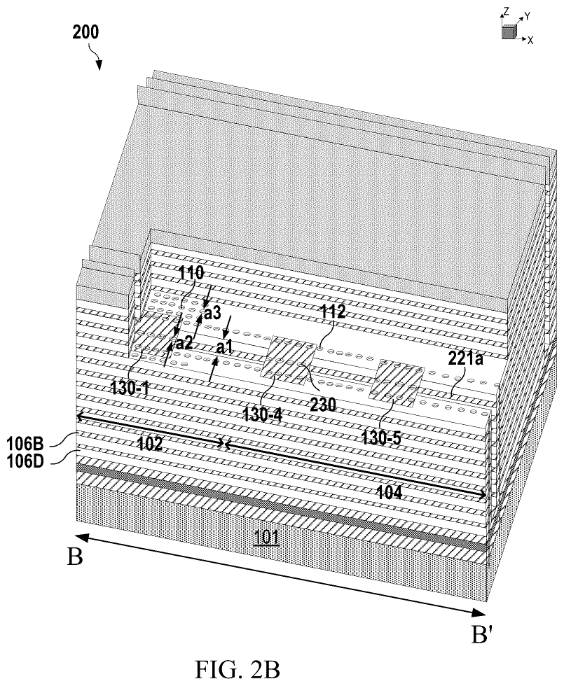

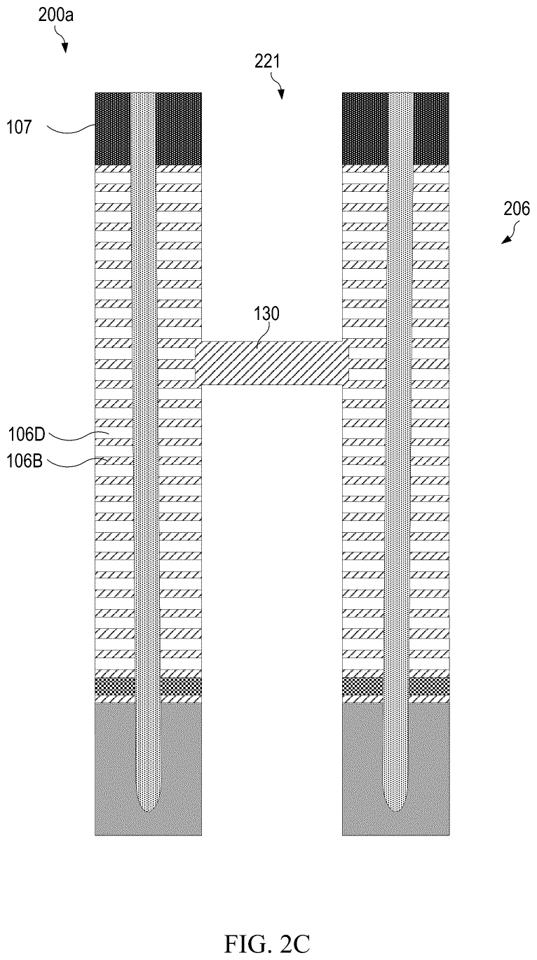

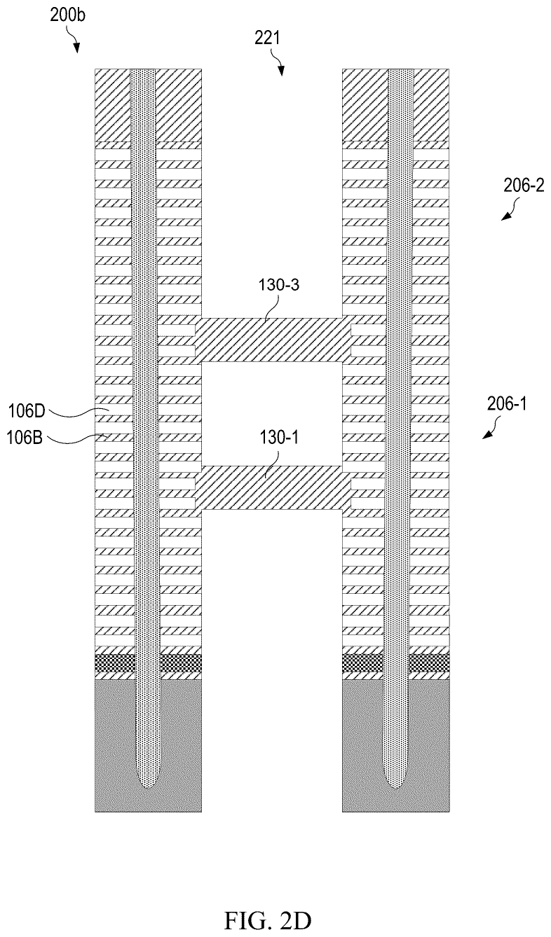

Referring back to FIG. 1B, the semiconductor device 100 includes one or more isolating structures 130. For example, FIG. 1B only shows one isolating structure 130, the other isolating structures 130 (as shown in FIG. 2B) can be arranged at the same vertical position along the X direction. The isolating structures 130 can serve as bridging structures across the first memory block 132a and the second memory block 132b, so that the structure of the stack 106 can be more stable. The isolating structures 130 can include a dielectric material (e.g., silicon oxide). Each isolating structure 130 has a first portion 130a in the stack 106, e.g., between two conductive layers 106A of the stack 106, and a second portion 130b in the gate line slit structures 120. The first portion 130a is in contact with at least one isolating layer 106B of the stack along the Y direction. The gate line slit structure 120 can extend through the second portion 130b of the isolating structure 130. In some implementations, since the second portion 130b undergoes more etching processes than the first portion 130a during fabrication processes of the semiconductor device 100, a size of the first portion 130a is greater than a size of the second portion 130b along the Z direction. For example, as shown in FIG. 1B, a length d1 of the first portion 130a is greater than a length d2 of the second portion 130b. Further, in some implementations, the length d1 of the first portion 130a is greater than a length d3 of an isolating layer 106B (e.g., the isolating layer 106B that is in contact with the first portion 130a of the isolating structure 130 along the Y direction) of the stack 106. The lengths d1, d2 and d3 are measured along the Z direction.

The gate line slit structure 120 extends through the isolating structure 130, such that a portion of the gate line slit structure 120 penetrates through the second portion 130b of the isolating structure 130 via openings (e.g., openings 230 of FIG. 2B) in the second portion 130b. In some implementations, a size of the portion of the gate line slit structure 120 penetrating through the second portion 130b is greater than a size of the channel structure 110 along the Y direction. For example, as shown in FIG. 1B, the length a2 of the portion of the gate line slit structure 120 is greater than a diameter a3 of the channel structure 110. Further, the length a1 of the gate line slit structure 120 above or below the isolating structure 130 is greater than the length a2. A length a4 of the isolating structure 130 is greater than the length a1. The lengths a1, a2 and a4 are measured along the Y direction. In some implementations, the length a2 is the same as, or substantially the same as a diameter of an opening 230 in the second portion 130b of the isolating structure 130.

The stack 106 is provided over the substrate 101. The substrate 101 can be any suitable semiconductor substrate having any suitable semiconductor material, such as monocrystalline, polycrystalline or single crystalline semiconductor. For example, the substrate 101 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the substrate 101 is kept in the semiconductor device 100. In some implementations, the substrate 101 can be removed from the semiconductor device 100 in a later process to expose ends of the channel structures 110. Further, the isolating layer, the dielectric layer and the isolating layer at the exposed ends of the channel structures 110 can be removed to expose the channel layer of the channel structures 110. A semiconductor layer (not shown in FIG. 1B) can be deposited to be in contact with the exposed channel layers of different channel structures 110 (e.g., all channel structures 110 of a memory block) to form a common source.

The stack 106 can extend in the second horizontal direction (e.g., the Y direction) that is parallel to a top surface of the substrate 101 and perpendicular to the first horizontal direction (e.g., the X direction). The conductive layers 106A and the isolating layers 106B can alternate in a vertical direction (e.g., Z direction) perpendicular to the second horizontal direction. The conductive layers 106A can be the same or different from each other in thickness, for example, ranging from 10-500 nm, e.g., about 35 nm. The isolating layers 106B can also be the same or different from each other in thickness, for example, ranging from 10-500 nm, e.g., about 25 nm. It should be noted that the number of the conductive layers 106A and the isolating layers 106B shown in FIG. 1B is for illustration only and that any suitable number of the conductive layers 106A and the isolating layers 106B can be included in the stack 106. The conductive layers 106A can include any suitable conducting material, such as tungsten (W), cobalt (Co), copper (Cu), aluminum (Al), titanium nitride (TiN), polycrystalline silicon (polysilicon), doped silicon, silicides, or any combination thereof. The isolating layers 106B can include a dielectric material, such as silicon oxide, silicon nitride, silicon oxynitride, or any combination thereof. In some implementations, the isolating layers 106B can also include high-K dielectric materials, such as hafnium oxide, zirconium oxide, aluminum oxide, tantalum oxide, lanthanum oxide, or any combination thereof.

FIGS. 2A-2D illustrate a semiconductor structure 200 at a stage during fabrication processes to manufacture the semiconductor device 100 of FIGS. 1A-1B. The semiconductor structure 200 includes a stack 206 of isolating layers 106B and sacrificial layers 106D alternating with each other along the Z direction. The sacrificial layers 106D can be made of a dielectric material, such as silicon nitride, that is different from the material of the isolating layer 106B. In a later process, at least a portion of the sacrificial layers 106D will be removed to form conductive layers 106A in replace of the sacrificial layers 106D, so that the stack 106 can be formed based on the stack 206. In addition, the semiconductor structure 200 has one or more gate line spaces 221a, 221b (collectively 221) extending along the Z direction through the stack 206. In a later stage of the fabrication process, a filling material (e.g., polysilicon, a high-K dielectric material, silicon oxide, carbon, etc.) can be filled in the gate line space 221 to form the gate line slit structure 120. The Y-Z plane shown in FIG. 2A shows the semiconductor structure 200 along cut line AA′ of FIG. 1A, and the X-Z plane shown in FIG. 2B shows a cross-section view of the semiconductor structure 200 along cut line BB′ of FIG. 1A.

As shown in FIG. 2A, the semiconductor structure 200 includes one or more isolating structures 130-1, 130-2 (collectively 130). Each of the isolating structures 130 has a first portion in the stack 206 (e.g., between two sacrificial layers 106D) and a second portion in the gate line space 221. The isolating structures 130 can offer mechanical support to prevent the stack 206 from collapsing towards the gate line space 221. As mentioned with reference to FIG. 1B, a length d1 of the first portion of the isolating structure 130 is greater than a length d2 of the second portion of the isolating structure. Further, the length d1 of the first portion is greater than a length d3 of the isolating layer 106B that is in contact with the isolating structure 130 along the Y direction. The lengths d1, d2 and d3 are measured along the Z direction.

For example, an isolating structure 130-1 extends across a first gate line space 221a, so that a portion of the isolating structure 130-1 is in a first gate line slit structure formed in the first gate line space 221a. An isolating structure 130-2 extends across a second gate line space 221b, so that a portion of the isolating structure 130-2 is in a second gate line slit structure formed in the second gate line space 221b.

The semiconductor structure 200 can have one or more stacks 206 between the surface layer 107 and the substrate 101. Each stack 206 can be provided with one or more isolating structures 130. After the sacrificial layers 106D are replaced with conductive layers 106A, the one or more stacks 206 can form one or more stacks 106, such that each stack 106 can be provided with one or more isolating structures 130.

In some implementations, as shown in FIG. 2C, the semiconductor structure 200a can include a stack 206 between the surface layer 107 and the substrate 101. The stack 206 includes isolating layers 106B and sacrificial layers 106D alternating with each other along the Z direction. An isolating structure 130 is provided between two sacrificial layers 106D of the stack 206. In some implementations, more than one isolating structure 130 is provided for the stack 206. In some other implementations, as shown in FIG. 2D, the semiconductor structure 200b can include a first stack 206-1 and a second stack 206-2 between the surface layer 107 and the substrate 101. Each of the first stack 206-1 and the second stack 206-2 include isolating layers 106B and sacrificial layers 106D alternating with each other along the Z direction. An isolating structure 130-1 is provided between two sacrificial layers 106D of the stack 206-1, and an isolating structure 130-3 is provided between the first stack 206-1 and the second stack 206-2. In some implementations, one or more isolating structures 130 can also be provided between sacrificial layers 106D of the second stack 206-2.

As shown in FIG. 2B, the semiconductor structure 200 can include a plurality of isolating structures 130 that are arranged along the gate line space 221a along the X direction. The isolating structures are distanced from one another. For example, the isolating structure 130-1 is arranged in the array region 102 of the semiconductor structure 200, and the isolating structures 130-4, 130-5 are arranged in the connection region 104 of the semiconductor structure 200. In some implementations, in the connection region 104, the semiconductor structure 200 includes a row of dummy channel structures 112 arranged along the X direction on each side of the gate line space 221a. A length of the isolating structure 130 along the Y direction is greater than a length of the gate line space 221a along the Y direction, and is less than a length of the tunnel region (e.g., the tunnel region 109 of FIG. 1A) along the Y direction.

The portion of each isolating structure in the gate line space 221 can have a plurality of openings 230. As such, when forming the gate line slit structure 120, the filling materials can fill the gate line space 221 through the openings 230, so that the gate line slit structure 120 can extend through the isolating structure 130.

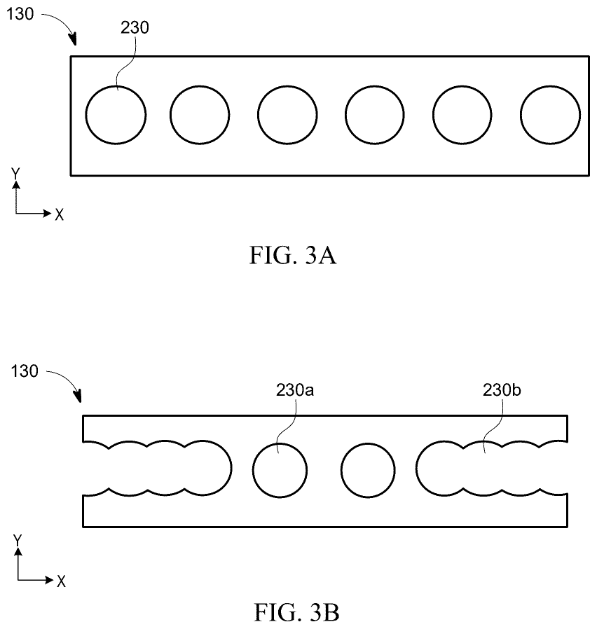

In some implementations, as shown in FIG. 3A, the plurality of openings 230 in the second portion of the isolating structure 130 are in the shape of round holes arranged along the X direction. As such, the portion of the gate line slit structure 120 penetrating through the isolating structure 130 via the openings 230 are in the shape of a plurality of cylinders arranged along the X direction.

In some other implementations, as shown in FIG. 3B, a first portion of openings 230a in the second portion of the isolating structure 130 are in the shape of round holes, and a second portion of openings 230b are in the shape of trenches. Each opening 230b can have two surfaces that include a series of curves connected together along the X direction. In other words, the openings 230b can have wave-like or caterpillar-like surfaces. In some implementations, a cross section (e.g., in the X-Y plane) of the opening 230b has a shape of partial circles arranged in a line and connected together. In some implementations, an opening 230b is formed by first having a set of round holes that are arranged along the X direction and separate from each other, and then expanding the round holes so that they are connected to one another. As such, the portion of the gate line slit structure 120 penetrating through the isolating structure 130 via the openings 230a are in the shape of cylinders, while the portion of the gate line slit structure 120 penetrating through the isolating structure 130 via the openings 230b have surfaces that include a series of curves, similar to the surfaces of the openings 230b.

It should be noted that FIGS. 2A-2D are for illustrative purpose. The semiconductor structure 200 can include any suitable number of stacks 206, and that each stack 206 can be provided with any suitable number of isolating structures 130.

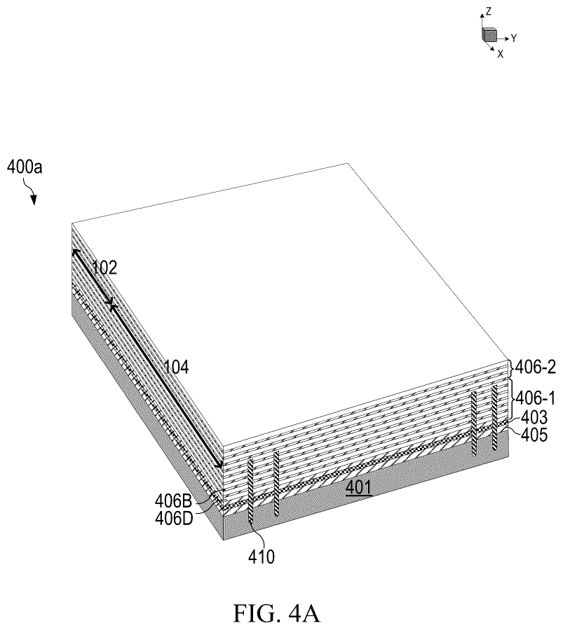

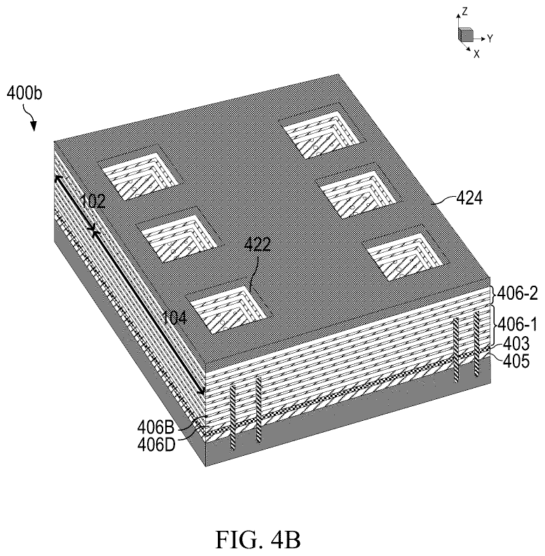

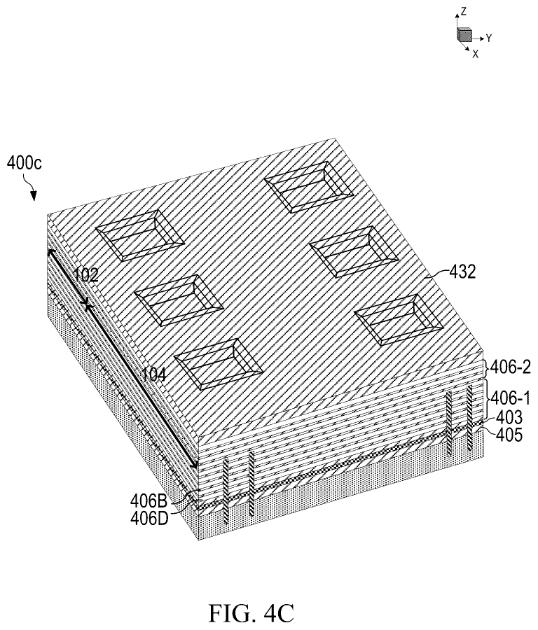

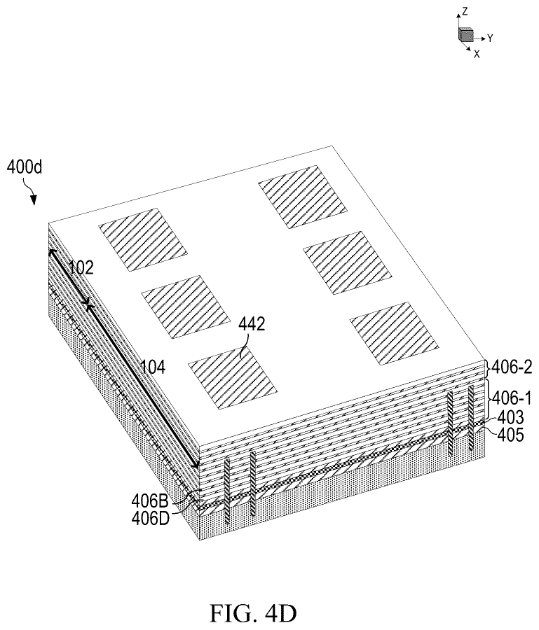

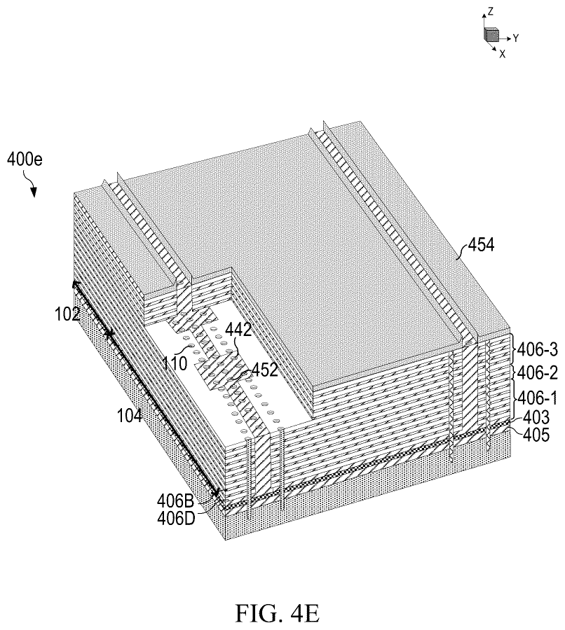

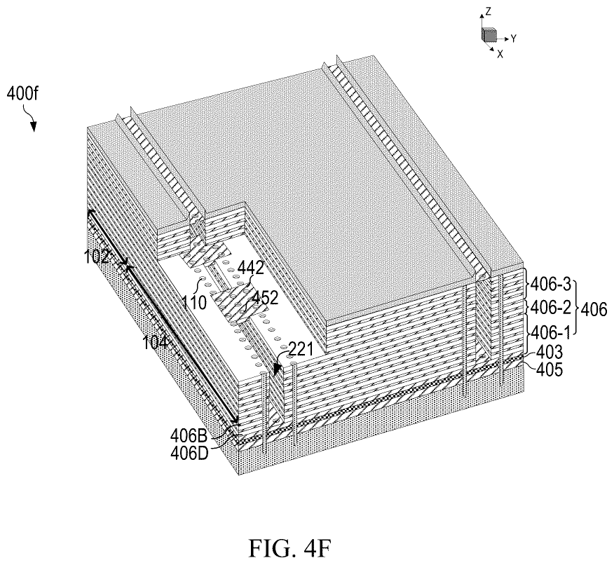

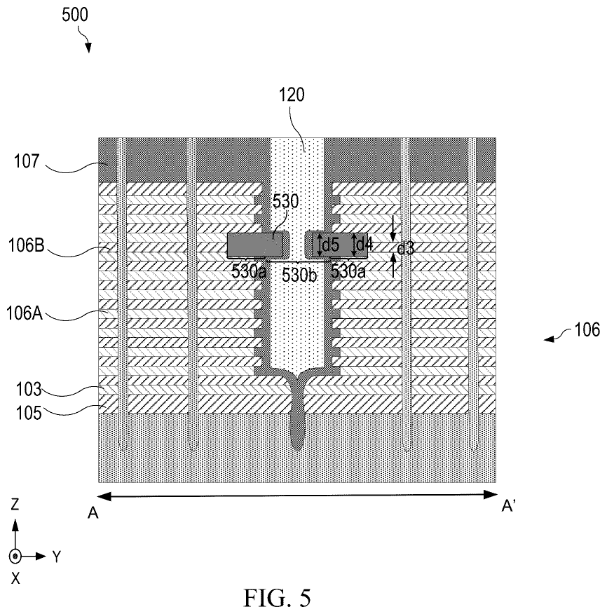

FIGS. 4A-4F illustrate an example process of fabricating a semiconductor device, such as the semiconductor device as illustrated in FIGS. 1A-1B. FIGS. 4A-4F show example semiconductor structures along at various stages of the fabrication process.

As shown in FIG. 4A, a semiconductor structure 400a is formed. The semiconductor structure 400a includes a substrate 401 and a stack 406-1 of alternating sacrificial layers 406D (e.g., sacrificial layers 106D of FIG. 2A) and isolating layers 406B (e.g., isolating layer 106B of FIG. 2A) provided over the substrate 401. The sacrificial layers 406D and the isolating layers 406B can alternate with each other along the vertical direction (e.g., the Z direction). The isolating layers 406B can include a dielectric material, such as silicon oxide, silicon nitride, silicon oxynitride, or any combination thereof. In some implementations, the sacrificial layers 406D can include a dielectric material different from the dielectric material of the isolating layers 406B. For example, the isolating layers 406B can include silicon oxide, and the sacrificial layers 406D can include silicon nitride. In some implementations, the semiconductor structure 400a can further include an oxide layer 405 and a semiconductor layer 403 between the stack 406-1 and the substrate 401 along the vertical direction.

The semiconductor structure 400a can include an array region 102 and a connection region 104 adjacent to the array region 102. The stack 406-1 can include channel holes 410 and gate line holes (e.g., gate line holes 452 of FIG. 4E) that extend along the Z direction through the stack 406-1 into the substrate 401. Channel holes 410 in the array region 102 can be used to form channel structures 110 of FIGS. 1A-1B, and channel holes 410 in the connection region 104 can be used to form dummy channel structures 112 of FIGS. 1A-1B. Gate line holes can be used to form the gate line slit structure 120 of FIGS. 1-2. In some implementations, a sacrificial material (e.g., carbon) is filled in the channel holes 410 and the gate line holes to offer mechanical support. In some implementations, a size (e.g. diameter) of the gate line holes is greater than a size (e.g., diameter) of the channel holes 410. The gate line holes and the channel holes 410 can be formed in a same photoetching process.

After forming the stack 406-1, another stack 406-2 of alternating sacrificial layers 406D and isolating layers 406B can be formed on the stack 406-1. The sacrificial layers 406D and isolating layers 406B of the stack 406-2 can have the same, or substantially the same thickness (e.g., a length along the Z direction) as the sacrificial layers 406D and isolating layers 406B of the stack 406-1. As an example, the stack 406-2 can include two or more pairs of sacrificial layers 406D and isolating layers 406B.

As shown in a semiconductor structure 400b of FIG. 4B, trenches 422 can be formed in the stack 406-2 by removing a portion of the stack 406-2. For example, the trenches 422 can be formed using a photo etching process, where the portion of the stack 406-2 covered by a photomask 435 is retained, and the portion of the stack 406-2 not covered by the photomask 435 is removed to expose the top layer of the stack 406-1. After the photo etching process, the photomask 435 can be removed. The trenches 422 are distanced from one another and arranged along the X direction in a row. In some implementations, some of the trenches of a row are in the array region 102, and some of the trenches of the row are in the connection region 104. In some implementations, more than one row of trenches 422 can be formed in the stack 406-2.

As shown in a semiconductor structure 400c of FIG. 4C, a dielectric material 432 (e.g., silicon oxide) can be filled into the trenches 422. For example, the dielectric material 432 can be deposited in the trenches 422 and on the surface of the stack 406-2. In some implementations, a semiconductor structure can be filled into the trenches 422.

As shown in a semiconductor structure 400d of FIG. 4D, the dielectric material 432 on the surface of the stack 406-2, which is excessive, can be removed by performing a planarization process, such as chemical mechanical polishing (CMP). As such, the semiconductor structure 400d can include a plurality of isolating patches 442 that each extends through the stack 406-2 along the Z direction. The thickness of the isolating patch 442 is greater than the thickness of an isolating layers 406B of the stack 406-2.

In some implementations, the isolating patches 442 can be formed by depositing an extra isolating layer (e.g., made of silicon oxide) on the stack 406-1. The extra isolating layer is thicker than the isolating layer 406B of the stack 406-1. Through a photo etching process, some portions of the extra isolating layer can be retained as the isolating patches, while other portions of the extra isolating layer can be removed. The second stack 407-2 can be formed by depositing Isolating layers 406B and sacrificial layers 406D in place of the removed portion of the extra isolating layer.

As shown in a semiconductor structure 400e of FIG. 4E, a stack 406-3 of alternating sacrificial layers 406D and isolating layers 406B can be formed on the stack 406-2. The semiconductor structure 400e can also include a cap oxide layer 454 on the stack 406-3. The cap oxide layer 454 and an adjacent oxide layer (e.g., formed at an earlier stage of the fabrication process) can be a combined oxide layer without a boundary in between.

Channel holes 410 can be formed through the stack 406-3 and the stack 406-2 to be connected with channel holes 410 in the stack 406-1. In some implementations, the sacrificial material in the channel holes 410 can be removed, and a first dielectric material (e.g., a silicon oxide), a second dielectric material (e.g., silicon nitride), the first dielectric material, and a semiconductor material (e.g., polysilicon) can be deposited, in sequence, on the inner surface of each channel hole 410. As such, channel structures 110 can be formed. Each channel structure 110 can include, from the outer edge to the center of the channel structure 110, an isolating layer (e.g., a silicon oxide layer), a dielectric layer (e.g., a silicon nitride layer), an isolating layer (e.g., a silicon oxide layer), and a channel layer (e.g., a polysilicon layer).

Gate line holes 452 can be formed through the stack 406-3 and the stack 406-2 to be connected with gate line holes in the stack 406-1. As shown in FIG. 4E, a portion of the gate line holes 452 extend through the isolating patches 442.

Further, a portion of the sacrificial layers 406D that are close to the gate line holes 452 are removed by a first etching process, such as wet etching using a first etchant (e.g., phosphoric acid). The first etchant can contact the sacrificial layers 406D via the gate line holes 452.

As shown in a semiconductor structure 400f of FIG. 4F, a portion of the isolating layers 406B that are close to the gate line holes 452 are removed by a second etching process, such as wet etching using a second etchant (e.g., hydrofluoric acid). Since the sacrificial layers 406D close to the gate line holes 452 are already removed, the second etchant can contact the isolating layers 406B from the top surface and the bottom surface of each isolating layer 406B. By controlling the usage of the second etchant, the isolating layers 406B that are close to the gate line holes 452 are removed, while the isolating patches 442, which is thicker than the isolating layers 406B, are at least partially retained. For example, the gate line holes 452 in the isolating layers 406B are expanded during the first and the second etching process, such that the expanded gate line holes are connected with one another to form the gate line space 221 having surfaces including a series of curves, as shown in FIG. 1C. The gate line holes 452 in the isolating patches 442 are also expanded during the second etching process, but since the isolating patches 442 is thicker, at least a portion of the gate line holes 452 in the isolating patches 442 are separate from each other. As such, the remaining portion of each isolating patch 442 is not disconnected at the gate line space 221. The remaining portion of each isolating patch 442 can therefore be the isolating structure 130 serving as a bridging structure to stabilize the stack 406 (including the stack 406-1, the stack 406-2, and the stack 406-3). In some implementations, the stack 406 is less likely to collapse towards the gate line space 221, especially in heat treatment in a later stage of the fabrication process, as compared to the scenario where no isolating structures 130 are provided.

Further, the isolating structures 130 are only arranged in selected areas of the connection region 104, and are not arranged in areas where contact structures (e.g., contact structures 116 of FIG. 1A) are formed. Therefore, the process of forming the contact structures in the connection region 104 can remain the same as if no isolating structures 130 are provided. In comparison, if a layer that is thicker than the isolating layer 406B and covers the entire connection region 104 is used as a bridging structure to stabilize the stack, forming the contact structures in the connection region 104 may take extra and/or different steps.

Further fabrication processes can be performed on the semiconductor structure 400f. For example, the sacrificial layers 406D in the array region 102 and in a part of the connection region 104 (e.g., the tunnel region 109) can be replaced with conductive layers to form the stack 106. The stack 406 in the remaining part of the connection region forms the stack 108.

The conductive material can be tungsten (W), cobalt (Co), copper (Cu), aluminum (Al), titanium nitride (TiN), polycrystalline silicon (polysilicon), doped silicon, silicides, or any combination thereof.

Further, the gate line space 221 can be filled with a filling material to form the gate line slit structure 120. The filling material can be a semiconductor material (e.g., polysilicon), a high-K dielectric material (e.g., hafnium oxide, zirconium oxide, aluminum oxide, tantalum oxide, lanthanum oxide, or any combination thereof), a dielectric material (e.g., silicon oxide) or a sacrificial material (e.g., carbon).

FIG. 5 illustrates a cross-sectional view of a semiconductor device 500. Similar to the semiconductor device 100, the semiconductor device 500 includes a stack 106 of alternating conductive layers 106A and isolating layers 106B, a gate line slit structure 120 extending along the Z direction through the stack 106, and channel structures 110 extending along the Z direction through the stack 106. Different from the semiconductor device 100 of FIGS. 1A-1C, which includes one or more isolating structures 130 made of a dielectric material (e.g., silicon oxide), the semiconductor device 500 includes one or more isolating structures 530 made of a semiconductor material (e.g., polysilicon). Each isolating structure 530 has a first portion 530a in the stack 106, e.g., between two conductive layers 106A of the stack 106, and a second portion 530b in the gate line slit structures 120.

In some implementations, since the second portion 530b is not etched during the etching process (e.g., as shown in FIG. 4F) to remove a portion of the isolating layers 406B, a size of the first portion 530a is equal to a size of the second portion 530b along the Z direction. For example, as shown in FIG. 5, a length d4 of the first portion 530a is equal to a length d5 of the second portion 530b. Further, in some implementations, the length d4 of the first portion 530a does not have to be greater than a length d3 of an isolating layer 106B of the stack 106. D4 can be equal to, or less than d3. The lengths d3, d4 and d5 are measured along the Z direction.

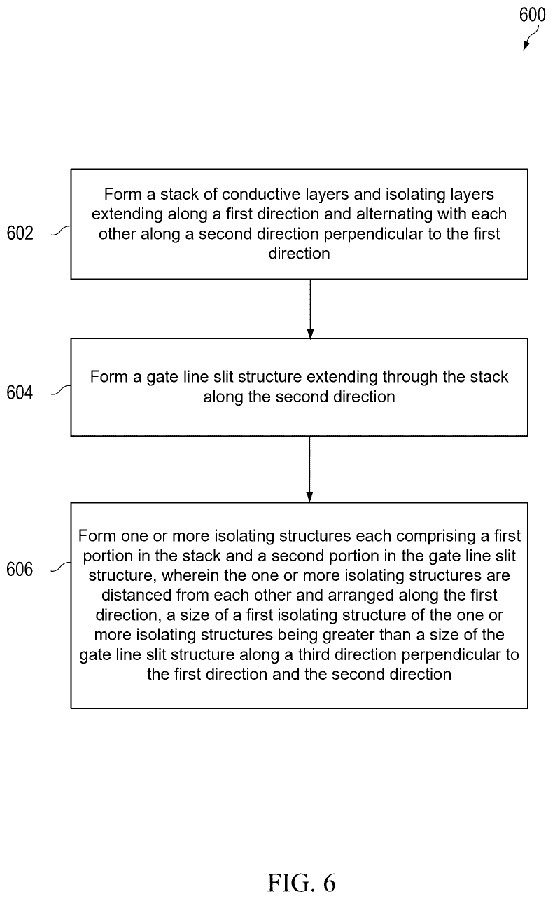

FIG. 6 illustrates a flow chart of an example process 600. The process 600 can be performed to form a semiconductor device (e.g., the semiconductor device 100 of FIGS. 1A-1B, or the semiconductor device 500 of FIG. 5). The process 600 can be described in view of FIGS. 4A-4F. The process 600 can include one or more steps of the fabrication process of forming the semiconductor structures in FIGS. 4A-4F. It is understood that the operations shown in process 600 are not exhaustive and that other operations can be performed as well before, after, or between any of the illustrated operations. Further, some of the operations may be performed simultaneously, or in a different order than shown in FIG. 6.

At 602, a stack (e.g., the stack 106 of FIGS. 1A-1B) is formed. The first stack includes conductive layers (e.g., conductive layers 106A of FIG. 1B) and isolating layers (e.g., isolating layers 106B of FIG. 1B) that extends along a first direction (e.g., the X direction). The conductive layers and the isolating layers alternate with each other along a second direction (e.g., the Z direction) perpendicular to the first direction. The stack can be arranged in an array region (e.g., the array region 102 of FIG. 1A) and a part of the connection region (e.g., tunnel region 109 of the connection region 104 of FIG. 1B) of the semiconductor device.

At 604, a gate line slit structure (e.g., the gate line slit structure 120 of FIGS. 1A-1C) is formed. The gate line slit structure extends through the stack along the second direction. Forming the gate line slit structure includes forming gate line holes (e.g., gate lines holes 452 of FIG. 4E) that extend through a stack (e.g., the stack 406 of FIG. 4A), forming a gate line space (e.g., the gate line space 221 of FIG. 4F) by expanding the gate line holes so that the gate line holes are connected with each other, and filling the gate line space with a semiconductor material.

At 606, one or more isolating structure (e.g., the isolating structure 130 of FIG. 1B) is formed. The one or more isolating structure are distanced from another and arranged along the first direction. Each isolating structure includes a first portion (e.g., the first portion 130a of FIG. 1B) in the first stack and a second portion (e.g., the second portion 130b of FIG. 1B) in the gate line slit structure. A size (e.g., a4 in FIG. 1B) of the isolating structure is greater than a size (e.g., a1 in FIG. 1B) of the gate line slit structure along a third direction (e.g., the Y direction) perpendicular to the first direction and the second direction.

In some implementations, forming the one or more isolating structure includes forming a first stack (e.g., including the stack 406-1 and the stack 406-2 of FIG. 4A), and etching the first stack to form one or more trenches (e.g., trenches 422 of FIG. 4B) that are distanced from each other and arranged along the first direction. The one or more trenches can be filled with a dielectric material to form the one or more isolating patches (e.g., the isolating patches 442 of FIG. 4D). When forming the gate line space that extends through the stack, the isolating layers of the first stack, which are thinner, are etched away in the gate line space, while the isolating patches, which are thicker, are at least partially retained in the gate line space. The retained portion of the isolating patches can be the isolating structures.

In some implementations, a portion of the gate line slit structure penetrates through the second portion of the each of the one or more isolating structures (e.g., via openings 230 of FIGS. 3A-3B in the first isolating structure). The portion of the gate line slit structure can include a plurality of cylinders that are arranged along the first direction. In some implementations, the portion of the gate line slit structure includes a structure having a surface that includes a series of curves (e.g., similar to the surface of the opening 230b in FIG. 3B).

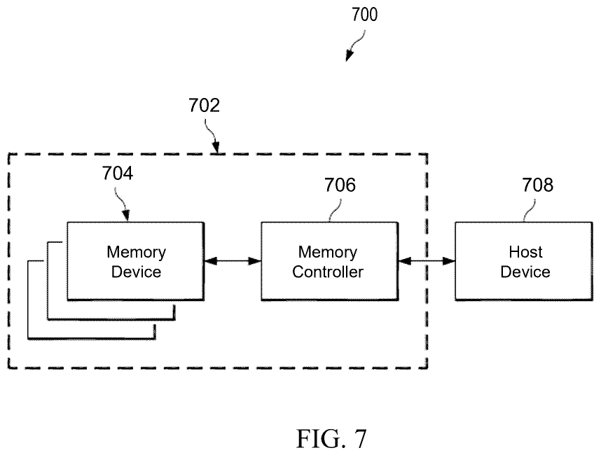

FIG. 7 illustrates a block diagram of an example system 700. The system 700 can have one or more semiconductor devices (e.g., memory devices), according to one or more implementations of the present disclosure. The system 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 5, the system 700 can include a host device 708 and a memory system 702 having one or more memory devices 704 and a memory controller 706. Host device 708 can include a processor of an electronic device, such as a central processing unit (CPU), or a system-on-chip (SoC), such as an application processor (AP). Host device 708 can be configured to send or receive data to or from the one or more memory devices 704.

A memory device 704 can be any memory device disclosed in the present disclosure, such as a semiconductor device (e.g., a NAND Flash memory) as shown in FIGS. 1A-1B. Memory controller 706 (a.k. a., a controller circuit) is coupled to memory device 704 and host device 708. Consistent with implementations of the present disclosure, memory device 704 can include a plurality of conductive interconnections through a cover layer that are in contact with conductive pads in a conductive pad layer, and memory controller 706 can be coupled to memory device 704 through at least one of the plurality of conductive interconnections. Memory controller 706 is configured to control memory device 704. For example, memory controller 706 may be configured to operate a plurality of channel structures via word lines. Memory controller 706 can manage data stored in memory device 704 and communicate with host device 708.

In some implementations, memory controller 706 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 706 can be configured to control operations of memory device 704, such as read, erase, and program (or write) operations. Memory controller 706 can also be configured to manage various functions with respect to the data stored or to be stored in memory device 704 including, but not limited to bad-block management, garbage collection, logical-to-physical address conversion, wear leveling, etc. In some implementations, memory controller 706 is further configured to process error correction codes (ECCs) with respect to the data read from or written to memory device 704. Any other suitable functions may be performed by memory controller 706 as well, for example, formatting memory device 704.

Memory controller 706 can communicate with an external device (e.g., host device 708) according to a particular communication protocol. For example, memory controller 706 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 706 and one or more memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 5, memory controller 706 and a single memory device 704 may be integrated into a memory card. Memory card can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” or “approximately” can indicate a value of a given quantity that varies within, for example, 10-30% of the value (e.g.,. +−.10%,. +−.20%, or. +−.30% of the value). As used herein, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first stack of conductive layers and isolating layers extending along a first direction and alternating with each other along a second direction perpendicular to the first direction;
a gate line slit structure extending through the first stack along the second direction; and
a first isolating structure comprises a first portion in the first stack and a second portion in the gate line slit structure, wherein the first portion of the first isolating structure is in contact with an isolating layer of the first stack,
wherein a size of the first portion of the first isolating structure is greater than a size of the isolating layer along the second direction.

2. The semiconductor device of claim 1, further comprising:
more than one first isolating structure distanced from each other and arranged along the first direction.

3. The semiconductor device of claim 1, wherein the size of the first portion is greater than a size of the second portion along the second direction.

4. The semiconductor device of claim 1, wherein the first portion of the first isolating structure is between two conductive layers of the first stack along the second direction.

5. The semiconductor device of claim 1, wherein the first isolating structure comprises a dielectric material or a semiconductor material.

6. The semiconductor device of claim 1, further comprising:
a second stack of conductive layers and isolating layers extending along the first direction and alternating with each other along the second direction, wherein the second stack is adjacent to the first stack along the second direction; and
a second isolating structure between the first stack and the second stack along the second direction.

7. The semiconductor device of claim 1, wherein a portion of the gate line slit structure penetrates through the second portion of the first isolating structure, and
wherein the portion of the gate line slit structure comprises a plurality of cylinders that are arranged along the first direction.

8. The semiconductor device of claim 7, wherein the portion of the gate line slit structure further comprises a structure having a surface that comprises a series of curves.

9. The semiconductor device of claim 7, further comprising channel structures extending through the first stack along the second direction,
wherein a size of the gate line slit structure is greater than a size of a channel structure along a third direction perpendicular to the first direction and the second direction.

10. The semiconductor device of claim 9, wherein a size of a cylinder of the plurality of cylinders is greater than the size of the channel structure along the third direction.

11. The semiconductor device of claim 1, wherein a surface of the gate line slit structure comprises a series of curves.

12. A semiconductor device, comprising:
a first stack of conductive layers and isolating layers extending along a first direction and alternating with each other along a second direction perpendicular to the first direction;
a gate line slit structure extending through the first stack along the second direction; and
one or more first isolating structures each comprising a first portion in the first stack and a second portion in the gate line slit structure, wherein the one or more first isolating structures are distanced from each other and arranged along the first direction,
wherein a size of a first isolating structure of the one or more first isolating structures is greater than a size of the gate line slit structure along a third direction perpendicular to the first direction and the second direction.

13. The semiconductor device of claim 12, wherein the semiconductor device comprises an array region and a connection region adjacent to the array region along the first direction, wherein the first stack is in the array region and a part of the connection region,
wherein a first portion of the one or more first isolating structures are in the array region, and a second portion of the one or more first isolating structures are in the part of the connection region.

14. The semiconductor device of claim 12, wherein a size of the first portion of the first isolating structure is greater than a size of the second portion of the first isolating structure along the second direction.

15. The semiconductor device of claim 12, further comprising:
a second stack of conductive layers and isolating layers extending along the first direction and alternating with each other along the second direction, wherein the second stack is adjacent to the first stack along the second direction; and
one or more second isolating structures between the first stack and the second stack along the second direction, wherein the one or more second isolating structures are arranged along the first direction.

16. The semiconductor device of claim 12, further comprising channel structures extending through the first stack along the second direction,
wherein a size of the gate line slit structure is greater than a size of a channel structure along a third direction perpendicular to the first direction and the second direction.

17. The semiconductor device of claim 12, wherein a surface of the gate line slit structure comprises a series of curves.

18. A method of forming a semiconductor device, comprising:
forming a stack of conductive layers and isolating layers extending along a first direction and alternating with each other along a second direction perpendicular to the first direction;
forming a gate line slit structure extending through the stack along the second direction; and
forming one or more isolating structures each comprising a first portion in the stack and a second portion in the gate line slit structure, wherein the one or more isolating structures are distanced from each other and arranged along the first direction,
wherein a size of a first isolating structure of the one or more isolating structures is greater than a size of the gate line slit structure along a third direction perpendicular to the first direction and the second direction.

19. The method of claim 18, further comprising:
forming a first stack of sacrificial layers and isolating layers alternating with each other along the second direction;
etching the first stack to form one or more trenches that are distanced from each other and arranged along the first direction;
filling the one or more trenches with a dielectric material to form the one or more isolating structures;
forming, on the first stack, a second stack of sacrificial layers and isolating layers alternating with each other along the second direction;
forming gate line holes extending through the second stack of sacrificial layers and isolating layers, the one or more isolating structures, and the first stack of sacrificial layer and isolating layers, wherein the gate line holes are arranged along the first direction; and
forming a gate line space by expanding the gate line holes, wherein the gate line holes in the first stack and the second stack are connected with each other along the first direction to form the gate line space, and wherein at least a portion of the gate line holes in the one or more isolating structures are separate from each other.

20. The method of claim 19, wherein forming the stack of conductive layers and isolating layers comprises replacing the sacrificial layers of the first stack and the second stack with conductive layers, and
wherein forming the gate line slit structure comprises filling the gate line space with a semiconductor material.
